(19) United States
(12) Patent Application Publication
(10) Pub. No.: US 2026/0173685 A1
(43) Pub. Date: Jun. 18, 2026

(54) DISPLAY DEVICE AND ELECTRONIC DEVICE

(71) Applicant: Samsung Display Co., Ltd., Yongin-si (KR)

(72) Inventors: Won Jun LEE, Yongin-si (KR); Soo Dong Kim, Yongin-si (KR); Rae Young Kim, Yongin-si (KR); Chol Ho Kim, Yongin-si (KR); Hae Ryeong Park, Yongin-si (KR); Je Won Yoo, Yongin-si (KR)

(73) Assignee: Samsung Display Co., Ltd., Yongin-si (KR)

(21) Appl. No.: 19/354,259

(22) Filed: Oct. 9, 2025

(30) Foreign Application Priority Data
Dec. 16, 2024 (KR) 10-2024-0186733

(51) Int. Cl. H10K 59/131; H10K 59/88

(52) U.S. Cl. CPC H10K 59/131; H10K 59/88

(57) ABSTRACT

A display device includes a sub-pixel in a real display area of a display area of a display panel; a dummy sub-pixel in a dummy area of a non-display area of the display panel; a first driving voltage line and a second driving voltage line connected to a power supply circuit, wherein the first driving voltage line comprises an outer driving voltage line in the non-display area and an inner driving voltage line in the display area and the dummy area, the second driving voltage line comprises a connection line in the non-display area, a vertical driving voltage line and a horizontal driving voltage line in the display area and the dummy area. A first portion of the vertical driving voltage line is cut in the dummy area and a second portion of the vertical driving voltage line is connected to the first driving voltage line in the dummy area.

### CROSS-REFERENCE TO RELATED APPLICATION

This application is based on and claims priority from Korean Patent Application No. 10-2024-0186733 filed on Dec. 16, 2024 in the Korean Intellectual Property Office, and all the benefits accruing therefrom under 35 U.S.C. 119, the contents of which in its entirety are incorporated herein by reference.

### BACKGROUND

### 1. Field

The present disclosure relates to a display device and an electronic device.

### 2. Description of Related Art

An organic light emitting display device includes a display element of which luminance is changed by current, for example, an organic light emitting diode.

### SUMMARY

Aspects of the present disclosure provide a display device and an electronic device capable of reducing power consumption.

According to an aspect of an example embodiment of the present disclosure, there is provided a display device comprising: a display panel having a display area and a non-display area; a circuit board connected to the non-display area; a sub-pixel in a real display area of the display area; a dummy sub-pixel in a dummy area of the non-display area; a first driving voltage line connected to a power supply circuit of the circuit board; and a second driving voltage line connected to the power supply circuit, wherein the first driving voltage line comprises an outer driving voltage line in the non-display area and an inner driving voltage line in the display area and the dummy area, wherein the second driving voltage line comprises a connection line in the non-display area, a vertical driving voltage line in the display area and in the dummy area, and a horizontal driving voltage line in the display area and in the dummy area, and wherein a first portion of the vertical driving voltage line is cut in the dummy area and a second portion of the vertical driving voltage line is connected to the first driving voltage line in the dummy area.

According to an aspect of an example embodiment of the present disclosure, there is provided an electronic device comprising a display device, wherein the display device comprises: a display panel having a display area and a non-display area; a circuit board connected to the non-display area; a sub-pixel in a real display area of the display area; a dummy sub-pixel in a dummy area of the non-display area; a first driving voltage line connected to a power supply circuit of the circuit board; and a second driving voltage line connected to the power supply circuit, wherein the first driving voltage line comprises an outer driving voltage line in the non-display area and an inner driving voltage line in the display area and the dummy area, wherein the second driving voltage line comprises a connection line in the non-display area, a vertical driving voltage line in the display area and in the dummy area, and a horizontal driving voltage line in the display area and in the dummy area, and wherein a first portion of the vertical driving voltage line is cut in the dummy area and a second portion of the vertical driving voltage line is connected to the first driving voltage line in the dummy area.

### BRIEF DESCRIPTION OF DRAWINGS

The above and other aspects and features of the present disclosure will become more apparent by describing in detail example embodiments thereof with reference to the attached drawings, in which:

FIG. 1 is an exploded perspective view showing a display device according to one embodiment;

FIG. 2 is a block diagram illustrating a display device according to one embodiment;

FIG. 3 is an equivalent circuit diagram of a first sub-pixel according to one embodiment;

FIG. 4 is a layout diagram illustrating an example of a display panel according to one embodiment;

FIGS. 5 and 6 are layout diagrams illustrating examples of a display area of FIG. 4;

FIG. 7 is a cross-sectional view illustrating an example of a display panel taken along line I1-I1′ of FIG. 5;

FIG. 8 is a cross-sectional view showing area A1 of FIG. 7 in detail;

FIG. 9 is a diagram for describing an image correction method of a display device according to one embodiment;

FIG. 10 is a plan view of a display device according to one embodiment;

FIG. 11 is an enlarged view of a portion of a first dummy area of FIG. 10;

FIG. 12 is a view in which vertical driving voltage lines, horizontal driving voltage lines, and inner driving voltage lines are added to FIG. 11;

FIG. 13 is a plan view of a display device according to one embodiment;

FIG. 14 is a drawing for describing an effect of reducing voltage drop of a display device according to one embodiment;

FIG. 15 is a block diagram of an electronic device according to one embodiment; and

FIGS. 16, 17 and 18 are schematic diagrams illustrating electronic devices according to various embodiments.

### DETAILED DESCRIPTION

The present disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, example embodiments will be described with reference to the accompanying drawings.

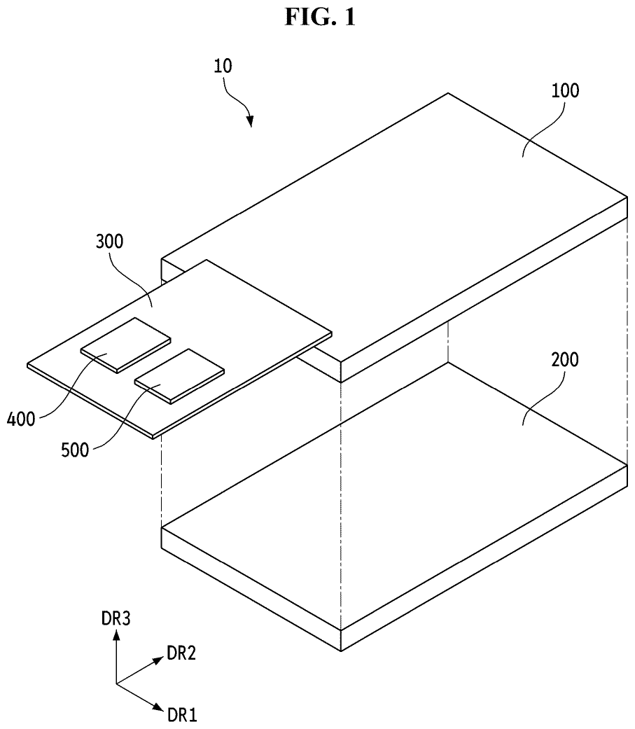

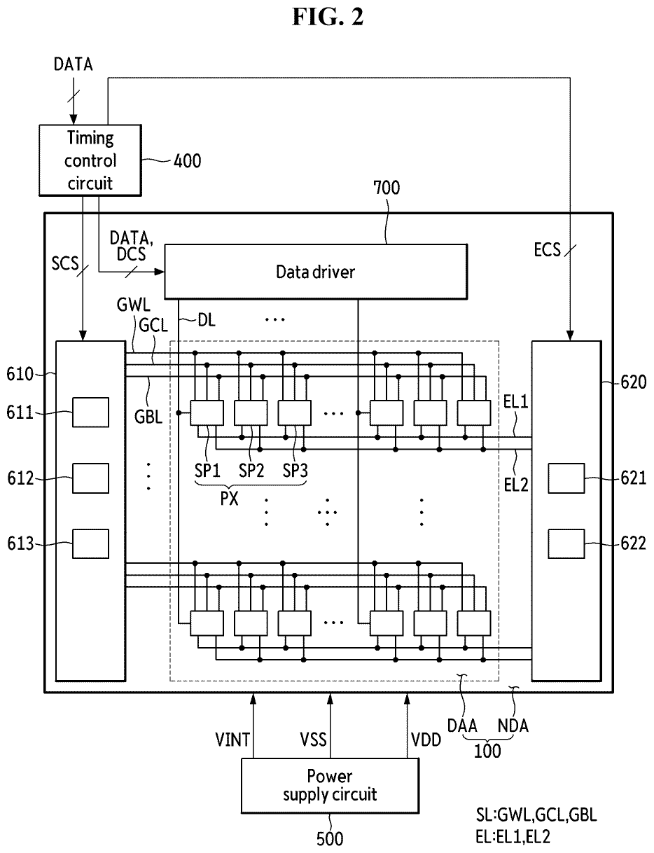

FIG. 1 is an exploded perspective view showing a display device according to one embodiment. FIG. 2 is a block diagram illustrating a display device according to one embodiment.

Referring to FIGS. 1 and 2, a display device 10 according to one embodiment may display a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to one embodiment may be applied as a display unit of a television, a laptop, a monitor, a billboard, an Internet-of-Things (IoT) terminal or the like. Alternatively, the display device 10 according to one embodiment may be applied to a smart watch, a watch phone, a head mounted display (HMD) for implementing virtual reality and augmented reality, and the like.

The display device 10 according to one embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side in a first direction DR1 and a long side in a second direction DR2 intersecting the first direction DR1. In the display panel 100, a corner where the short side in the first direction DR1 and the long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. A planar shape of the display device 10 may conform to the planar shape of the display panel 100, but the embodiment of the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may include a display area DAA displaying an image and a non-display area NDA not displaying an image as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

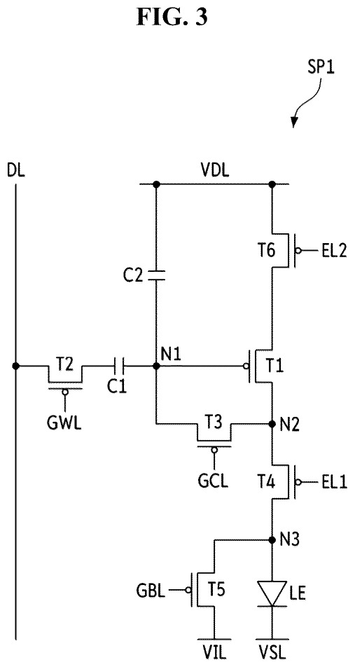

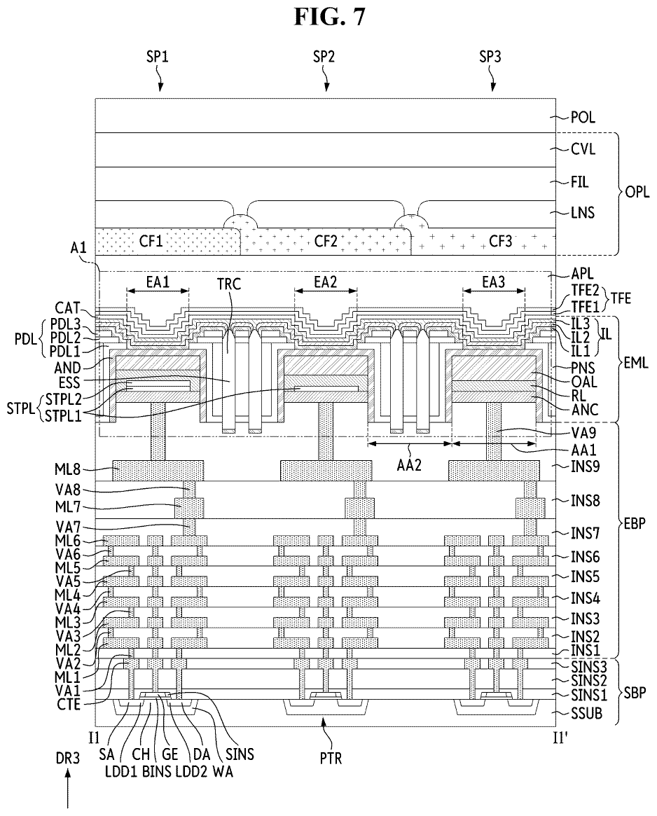

The plurality of pixels PX may include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and arranged on a semiconductor substrate SSUB (see FIG. 7). For example, the plurality of pixel transistors of the display panel 100 may include complementary metal oxide semiconductor (CMOS) transistors, but the embodiment of the present disclosure is not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may include CMOS transistors, but the embodiment of the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output the write scan signals sequentially to the write scan lines GWL. The control scan signal output unit 612 may generate control scan signals in response to the scan timing control signal SCS and sequentially output the control scan signals to the control scan lines GCL. The bias scan signal output unit 613 may generate bias scan signals according to the scan timing control signal SCS and output the bias scan signals sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may include CMOS transistors, but the embodiment of the present disclosure is not limited thereto.

The data driver 700 may receive digital video data DATA and a data timing control signal DCS from the timing control circuit 400. The data driver 700 may convert the digital video data DATA into analog data voltages according to the data timing control signal DCS and output the analog data voltages to the plurality of data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface of the display panel 100, for example, on a rear surface thereof. The heat dissipation layer 200 may dissipate heat generated from the display panel 100. The heat dissipation layer 200 may include a metal layer having high thermal conductivity, such as graphite, silver (Ag), copper (Cu), or aluminum (Al).

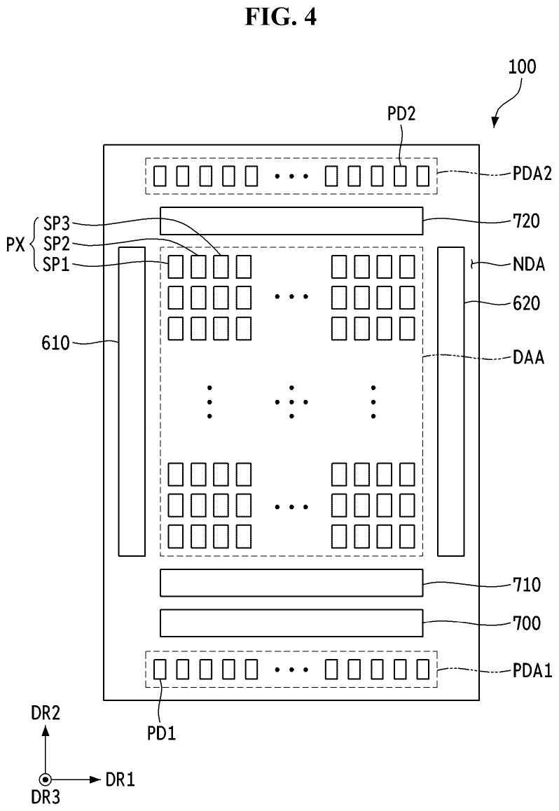

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, a first end portion of the circuit board 300 may be located on the rear surface of the display panel 100 and/or a rear surface of the heat dissipation layer 200. A second end portion of the circuit board 300 may be connected to the plurality of first pads PD1 (see FIG. 4) of the first pad portion PDA1 (see FIG. 4) of the display panel 100 by using a conductive adhesive member. The first end portion of the circuit board 300 may be opposite to the second end portion of the circuit board 300.

The timing control circuit 400 may receive digital video data and timing signals inputted from an outside. The timing control circuit 400 may generate the scan timing control signal SCS, the emission timing control signal ECS, and the data timing control signal DCS for controlling the display panel 100 based on the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate and supply a first driving voltage VSS, a second driving voltage VDD, and a third driving voltage VINT to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may include CMOS transistors, but the embodiment of the present disclosure is not limited thereto. Each of the timing control circuit 400 and the power supply circuit 500 may be located between the data driver 700 and the first pad portion PDA1 (see FIG. 4).

FIG. 3 is an equivalent circuit diagram of a first sub-pixel according to one embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor C1, and a second capacitor C2.

The light emitting element LE may emit light in response to a driving current Ids flowing through the channel of the first transistor T1. A light emission amount of the light emitting element LE may be proportional to the driving current Ids. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including the first electrode, the second electrode, and an organic light emitting layer located between the first electrode and the second electrode, but the embodiment of the present disclosure is not limited thereto. For example, the light emitting element LE may be an inorganic light emitting element including the first electrode, the second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between a source electrode and a drain electrode thereof according to a voltage applied to a gate electrode thereof. The first transistor T1 may include the gate electrode connected to a first node N1, the source electrode connected to a drain electrode of a sixth transistor T6, and the drain electrode connected to a second node N2.

A second transistor T2 may be located between one electrode of the first capacitor C1 and the data line DL. The second transistor T2 may be turned on by the write scan signal of the write scan line GWL to connect the one electrode of the first capacitor C1 to the data line DL. Accordingly, the data voltage of the data line DL may be applied to the one electrode of the first capacitor C1. The second transistor T2 may include a gate electrode connected to the write scan line GWL, a source electrode connected to the data line DL, and a drain electrode connected to the one electrode of the first capacitor C1.

A third transistor T3 may be located between the first node N1 and the second node N2. The third transistor T3 may be turned on by the write control signal of the write control line GCL to connect the first node N1 to the second node N2. For this reason, when the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be located between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor C2 may be formed between the first node N1 and the drain electrode of the second transistor T2. The first capacitor C1 may include one electrode connected to the drain electrode of the second transistor T2 and the other electrode connected to the first node N1.

The second capacitor C2 may be formed between the gate electrode of the first transistor T1 and the second driving voltage line VDL. The second capacitor C2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor C1, and the one electrode of the second capacitor C2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 may include six transistors T1 to T6 and two capacitors C1 and C2, it should be noted that the equivalent circuit diagram of the first sub-pixel SP1 is not limited to that shown in FIG. 3. For example, a number of transistors and a number of capacitors of the first sub-pixel SP1 are not limited to those shown in FIG. 3.

Further, an equivalent circuit diagram of the second sub-pixel SP2 and an equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one embodiment.

Referring to FIG. 4, the display area DAA of the display panel 100 according to one embodiment may include the plurality of pixels PX arranged in a matrix form. The non-display area NDA of the display panel 100 according to one embodiment may include the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. For example, the scan driver 610 may be located on a left side of the display area DAA, and the emission driver 620 may be located on a right side of the display area DAA. However, the embodiment of the present disclosure is not limited thereto. For example, the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2 (e.g., negative (−) second direction DR2). That is, the first pad portion PDA1 may be located closer to an edge of the display panel 100 than the data driver 700.

The second pad portion PDA2 may include a plurality of second pads PD2 corresponding to inspection pads that are used to test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2 (e.g., positive (+) second direction DR2). That is, the second pad portion PDA2 may be located closer to the edge of the display panel 100 than the second distribution circuit 720.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to P (P is a positive integer of 2 or more) data lines DL, and as a result, a number of the plurality of first pads PD1 may be reduced. The first distribution circuit 710 may be located on the third side of the display area DAA of the display panel 100. For example, the first distribution circuit 710 may be located on one side of the display area DAA in the second direction DR2 (e.g., negative (−) second direction DR2). That is, the first distribution circuit 710 may be located on a lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2 (e.g., positive (+) second direction DR2). That is, the second distribution circuit 720 may be located on an upper side of the display area DAA.

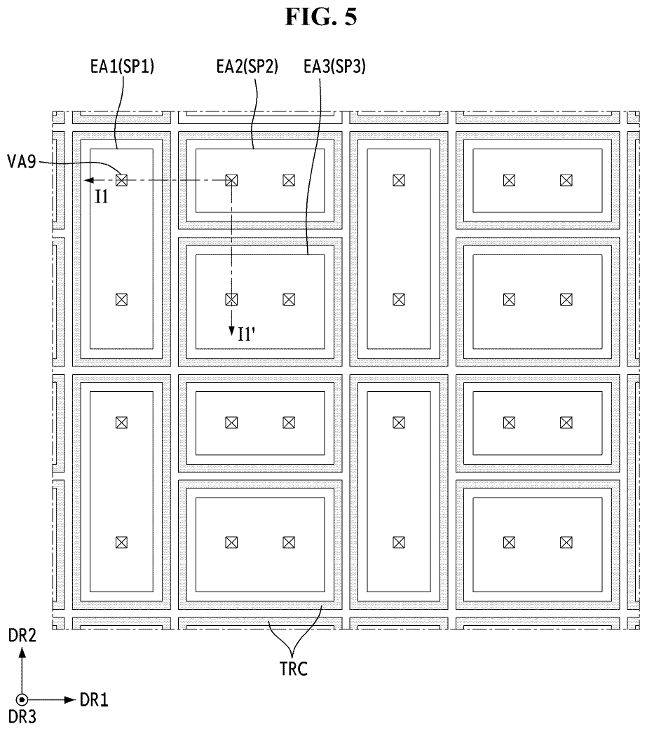

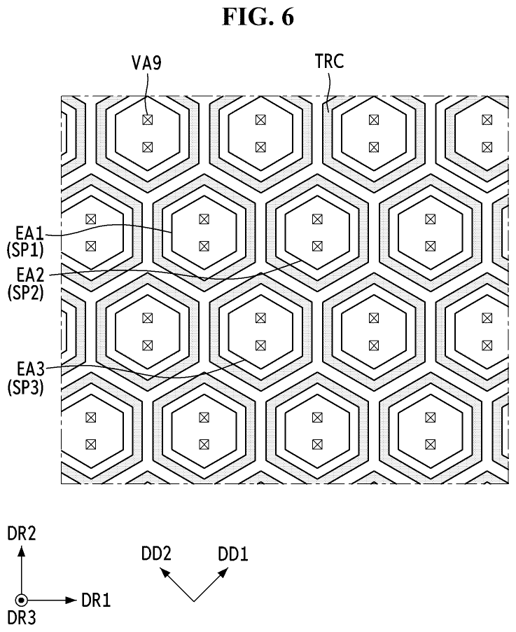

FIGS. 5 and 6 are layout diagrams illustrating examples of the display area of FIG. 4.

Referring to FIGS. 5 and 6, each of the pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have a polygonal, circular, elliptical, or atypical shape on a plan view.

A maximum length of the first emission area EA1 in the first direction DR1 may be less than a maximum length of the second emission area EA2 in the first direction DR1 and a maximum length of the third emission area EA3 in the first direction DR1. The maximum length of the second emission area EA2 in the first direction DR1 and the maximum length of the third emission area EA3 in the first direction DR1 may be substantially the same.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be less than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, on a plan view, a hexagonal shape including six straight lines as shown in FIGS. 5 and 6, but the embodiment of the present disclosure is not limited thereto. The first emission area EA1, the second emission area EA2, and the third emission area EA3 may have a polygonal shape other than a hexagon, a circular shape, an elliptical shape, or an atypical shape on a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. An area of the first emission area EA1, an area of the second emission area EA2, and an area of the third emission area EA3 may be different.

Alternatively, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light that has passed through a first color filter CF1 (see FIG. 7) among lights emitted from the first emission area EA1, the second sub-pixel SP2 may emit second light that has passed through a second color filter CF2 (see FIG. 7) among lights emitted from the second emission area EA2, and the third sub-pixel SP3 may emit third light that has passed through a third color filter CF3 (see FIG. 7) among lights emitted from the third emission area EA3.

The first light, the second light and the third light described above may be lights of different wavelength bands. For example, one of the first to third lights may be light in a blue wavelength band, another may be light in a green wavelength band, and the remaining one may be light in a red wavelength band. Here, the blue wavelength band may be a wavelength band of light whose main peak wavelength is in a range of approximately 370 nm to 460 nm, the green wavelength band may be a wavelength band of light whose main peak wavelength is in a range of approximately 480 nm to 560 nm, and the red wavelength band may be a wavelength band of light whose main peak wavelength is in a range of approximately 600 nm to 750 nm.

FIGS. 5 and 6 illustrate an example in which each of the plurality of pixels PX may include three emission areas EA1, EA2, and EA3, but the embodiment of the present disclosure is not limited thereto. For example, each of the plurality of pixels PX may include four emission areas.

In addition, a layout of the emission areas of the plurality of pixels PX is not limited to those illustrated in FIGS. 5 and 6. For example, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, on a plan view, a hexagonal shape are arranged as shown in FIG. 6.

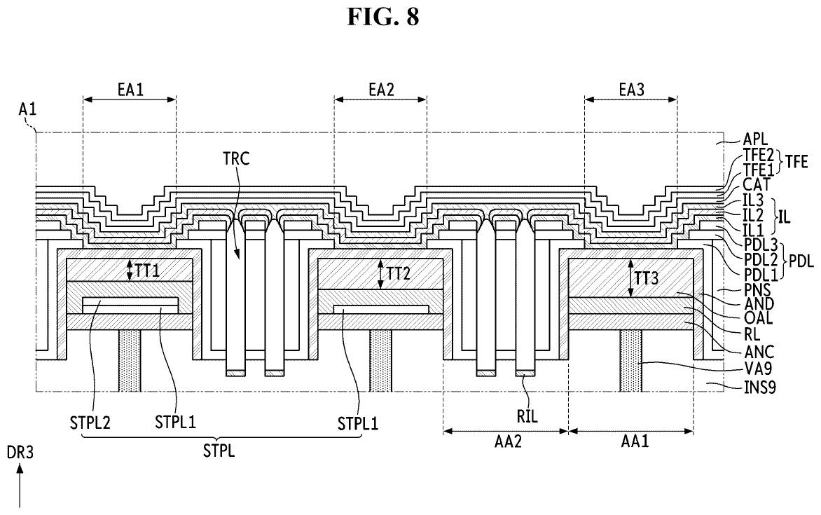

FIG. 7 is a cross-sectional view illustrating an example of a display panel taken along line I1-I1′ of FIG. 5. FIG. 8 is a cross-sectional view showing area A1 of FIG. 7 in detail.

Referring to FIGS. 7 and 8, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate, for example. The semiconductor substrate SSUB may be a substrate doped with a first type impurity. A plurality of well regions WA may be arranged on a top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH located between the source region SA and the drain region DA.

A lower insulating film BINS may be located between a gate electrode GE and the well region WA. A side insulating film SINS may be located on a side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further may include a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. A distance between the source region SA and the drain region DA may increase due to a presence of the first low-concentration impurity region LDD1 and the second low-concentration impurity region LDD2. Therefore, a length of the channel region CH of each of the pixel transistors PTR may increase, and punch-through and hot carrier phenomena that might be caused by a short channel may be reduced or prevented.

A first semiconductor insulating film SINS1 may be located on the semiconductor substrate SSUB. The first semiconductor insulating film SINS1 may include silicon carbonitride (SiCN) or a silicon oxide (SiOx)-based inorganic film, but the embodiment of the present disclosure is not limited thereto.

A second semiconductor insulating film SINS2 may be located on the first semiconductor insulating film SINS1. The second semiconductor insulating film SINS2 may include a silicon oxide (SiOx)-based inorganic film, but the embodiment of the present disclosure is not limited thereto.

The plurality of contact terminals CTE may be arranged on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. A top surface of each of the plurality of contact terminals CTE may be exposed without being covered by the third semiconductor insulating film SINS3. The third semiconductor insulating film SINS3 may include a silicon oxide (SiOx)-based inorganic film, but the embodiment of the present disclosure is not limited thereto.

The semiconductor substrate SSUB may be replaced with a glass substrate or a polymer resin substrate such as polyimide. In this case, thin film transistors may be arranged on the glass substrate or the polymer resin substrate. The glass substrate may be a rigid substrate that does not bend, and the polymer resin substrate may be a flexible substrate that may be bent or curved.

The light emitting element backplane EBP may include a plurality of conductive layers ML1 to ML8, a plurality of vias VA1 to VA9, and a plurality of insulating films INS1 to INS11. In addition, the light emitting element backplane EBP may include the plurality of insulating films INS1 to INS11 located between the first to eighth conductive layers ML1 to ML8.

The first to eighth conductive layers ML1 to ML8 may connect the plurality of contact terminals CTE exposed from the semiconductor backplane SBP to thereby implement a circuit of the first sub-pixel SP1 shown in FIG. 3. For example, the first to sixth transistors T1 to T6 may be formed in the semiconductor backplane SBP, and connection of the first to sixth transistors T1 to T6 and the first and second capacitors C1 and C2 may be accomplished through the first to eighth conductive layers ML1 to ML8. In addition, connection between the drain region corresponding to the drain electrode of the fourth transistor T4, the source region corresponding to the source electrode of the fifth transistor T5, and a first electrode AND of the light emitting element LE may be accomplished through the first to eighth conductive layers ML1 to ML8.

The first insulating film INS1 may be located on the semiconductor backplane SBP. Each of first vias VA1 may penetrate the first insulating film INS1 and be connected to the contact terminal CTE exposed from the semiconductor backplane SBP. Each of the first conductive layers ML1 may be located on the first insulating film INS1 and may be connected to the first via VA1.

The second insulating film INS2 may be located on the first insulating film INS1 and the first conductive layers ML1. Each of the second vias VA2 may penetrate the second insulating film INS2 and be connected to the exposed first conductive layer ML1. Each of the second conductive layers ML2 may be located on the second insulating film INS2 and may be connected to the second via VA2.

The third insulating film INS3 may be located on the second insulating film INS2 and the second conductive layers ML2. Each of the third vias VA3 may penetrate the third insulating film INS3 and be connected to the exposed second conductive layer ML2. Each of the third conductive layers ML3 may be located on the third insulating film INS3 and may be connected to the third via VA3.

A fourth insulating film INS4 may be located on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be located on the fourth insulating film INS4 and may be connected to the fourth via VA4.

A fifth insulating film INS5 may be located on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be located on the fifth insulating film INS5 and may be connected to the fifth via VA5.

A sixth insulating film INS6 may be located on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be located on the sixth insulating film INS6 and may be connected to the sixth via VA6.

A seventh insulating film INS7 may be located on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be located on the seventh insulating film INS7 and may be connected to the seventh via VA7.

An eighth insulating film INS8 may be located on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be located on the eighth insulating film INS8 and may be connected to the eighth via VA8.

The first to eighth conductive layers ML1 to ML8 and the first to eighth vias VA1 to VA8 may include substantially the same material. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material. First to eighth insulating films INS1 to INS8 may include silicon oxide (SiOx)-based inorganic films, but the embodiment of the present disclosure is not limited thereto.

Thicknesses of the first conductive layer ML1, the second conductive layer ML2, the third conductive layer ML3, the fourth conductive layer ML4, the fifth conductive layer ML5, and the sixth conductive layer ML6 may be greater than thicknesses of the first via VA1, the second via VA2, the third via VA3, the fourth via VA4, the fifth via VA5, and the sixth via VA6, respectively. A thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be located on the eighth insulating film INS8 and the eighth conductive layer ML8. The ninth insulating film INS9 may include a silicon oxide (SiOx)-based inorganic film, but the embodiment of the present disclosure is not limited thereto.

Each of the ninth vias VA9 may penetrate the ninth insulating film INS9 and be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

The display element layer EML may be located on the light emitting element backplane EBP. The display element layer EML may include a plurality of connection electrodes ANC, a plurality of reflective electrodes RL, a planarization film PNS, a pixel defining film PDL, a plurality of first electrodes AND, a light emitting stack IL, a second electrode CAT, and a plurality of trenches TRC.

Further, the display element layer EML may include the first emission area EA1, the second emission area EA2, and the third emission area EA3. Each of the first emission area EA1, the second emission area EA2, and the third emission area EA3 may be an area where the first electrode AND, the light emitting stack IL, and the second electrode CAT are sequentially stacked. Each of the first emission area EA1, the second emission area EA2, and the third emission area EA3 may be an area where the light emitting element LE including the first electrode AND, the light emitting stack IL, and the second electrode CAT is located. Each of the first emission area EA1, the second emission area EA2, and the third emission area EA3 may be partitioned by a first pixel defining film PDL1.

The ninth insulating film INS9 may include first areas AA1 overlapping the plurality of connection electrodes ANC and a second area AA2 located around the first areas AA1. A thickness of the first area AA1 of the ninth insulating film INS9 may be greater than a thickness of the second area AA2 of the ninth insulating film INS9.

The plurality of connection electrodes ANC may be respectively located on the first areas AA1 of the ninth insulating film INS9. Each of the plurality of connection electrodes ANC may be located on the corresponding first area AA1. The plurality of connection electrodes ANC may include titanium nitride (TiN) or a transparent conductive oxide. For example, the transparent conductive oxide may be indium tin oxide (ITO) or indium zinc oxide (IZO), but the embodiment of the present disclosure is not limited thereto.

A step layer STPL may include a first step layer STPL1 and a second step layer STPL2. The first step layer STPL1 and the second step layer STPL2 may include silicon carbonitride (SiCN) or a silicon oxide (SiOx)-based inorganic film, but the embodiment of the present disclosure is not limited thereto.

The first step layer STPL1 may be located on the connection electrode ANC in each of the first sub-pixels SP1 and the second sub-pixels SP2. Further, the second step layer STPL2 may be located on the first step layer STPL1 in each of the first sub-pixels SP1. The step layer STPL may not be located in each of the third sub-pixels SP3.

In each of the first sub-pixels SP1, reflective electrode RL may be located on the connection electrode ANC, the first step layer STPL1, and the second step layer STPL2. For example, in each of the first sub-pixels SP1, the reflective electrode RL may cover a top surface of the connection electrode ANC, a side surface of the first step layer STPL1, and a top surface and a side surface of the second step layer STPL2.

In each of the second sub-pixels SP2, the reflective electrode RL may be located on the connection electrode ANC and the first step layer STPL1. For example, in each of the second sub-pixels SP2, the reflective electrode RL may cover the top surface of the connection electrode ANC, and the top surface and the side surface of the first step layer STPL1.

In each of the third sub-pixels SP3, the reflective electrode RL may be located on the connection electrode ANC. For example, in each of the third sub-pixels SP3, the reflective electrode RL may cover the top surface of the connection electrode ANC.

Each of the reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the reflective electrodes RL may include aluminum (Al) with high reflectivity.

Optical auxiliary films OAL may be respectively located on the reflective electrodes RL. On each of the reflective electrodes RL, a corresponding optical auxiliary film OAL may be located. The optical auxiliary film OAL may include a silicon oxide (SiOx)-based inorganic film, but the present disclosure is not limited thereto.

Due to the first step layer STPL1 and the second step layer STPL2, a thickness TT1 of the optical auxiliary film OAL in the first sub-pixel SP1, a thickness TT2 of the optical auxiliary film OAL in the second sub-pixel SP2, and a thickness TT3 of the optical auxiliary film OAL in the third sub-pixel SP3 may be different. For example, due to the first step layer STPL1 and the second step layer STPL2, the thickness TT1 of the optical auxiliary film OAL in the first sub-pixel SP1 may be smallest. Further, the thickness TT3 of the optical auxiliary film OAL may be greatest in the third sub-pixel SP3 where the first step layer STPL1 and the second step layer STPL2 are not located. The thickness TT1 of the optical auxiliary film OAL in the first sub-pixel SP1 may be less than the thickness TT2 of the optical auxiliary film OAL in the second sub-pixel SP2. Further, the thickness TT1 of the optical auxiliary film OAL in the first sub-pixel SP1 may be less than the thickness TT3 of the optical auxiliary film OAL in the third sub-pixel SP3. Further, the thickness TT2 of the optical auxiliary film OAL in the second sub-pixel SP2 may be less than the thickness TT3 of the optical auxiliary film OAL in the third sub-pixel SP3.

A thickness of the first step layer STPL1 and a thickness of the second step layer STPL2 may be substantially the same or different from each other. Depending on a presence or absence and thicknesses of the first step layer STPL1 and the second step layer STPL2, the thickness TT1 of the optical auxiliary film OAL in the first sub-pixel SP1, the thickness TT2 of the optical auxiliary film OAL in the second sub-pixel SP2, and the thickness TT3 of the optical auxiliary film OAL in the third sub-pixel SP3 may be different. Therefore, the thickness TT1 of the first step layer STPL1 and the thickness TT2 of the second step layer STPL2 may be set in consideration of the main peak wavelength of the first light, the main peak wavelength of the second light, the main peak wavelength of the third light, a distance from the first stack layer IL1 to the reflective electrode RL in the first emission area EA1, and a distance from the second stack layer IL2 to the reflective electrode RL in the second emission area EA2 and, accordingly, a resonance distance of the first light, the resonance distance of the second light, and the resonance distance of the third light may be set.

FIGS. 7 and 8 illustrate two step layers, that is, the first step layer STPL1 and the second step layer STPL2, but the present disclosure is not limited thereto. When the resonance distance of the first light, the resonance distance of the second light, and the resonance distance of the third light may be optimally designed with only one step layer, any one of the first step layer STPL1 and the second step layer STPL2 may be omitted.

Further, FIGS. 7 and 8 illustrate that the first step layer STPL1 is located in the first sub-pixel SP1 and the second sub-pixel SP2, and the second step layer STPL2 is located in the first sub-pixel SP1, but the present disclosure is not limited thereto. Arrangement positions of the first step layer STPL1 and the second step layer STPL2 may be set in consideration of the main peak wavelength of the first light, the main peak wavelength of the second light, the main peak wavelength of the third light, and a distance from the first stack layer IL1 to the reflective electrode RL in the first emission area EA1, and a distance from the second stack layer IL2 to the reflective electrode RL in the second emission area EA2.

Each of the light emitting elements LE may include the first electrode AND, the light emitting stack IL, and the second electrode CAT.

The first electrode AND of each of the light emitting elements LE may be located on a side surface of the connection electrode ANC, a side surface of the reflective electrode RL, and a top surface and a side surface of the optical auxiliary film OAL. Since the first electrode AND of each of the light emitting elements LE is in contact with and electrically connected to the side surface of the reflective electrode RL and the side surface of the connection electrode ANC, a number of mask processes may be reduced compared to when the first electrode AND of each of the light emitting elements LE is connected to the reflective electrode RL exposed through a through hole penetrating the optical auxiliary film OAL. Accordingly, a manufacturing cost of the display panel (or display device) may be reduced and a manufacturing efficiency of the display panel (or display device) may be increased.

Further, since the thickness of the first area AA1 of the ninth insulating film INS9 is greater than the thickness of the second area AA2, a part of the ninth insulating film INS9 may be exposed in the first area AA1. Therefore, the first electrode AND of each of the light emitting elements LE may be located on a part of the ninth insulating film INS9 in the first area AA1. Therefore, a length of the first electrode AND in the third direction DR3 may be greater than a sum of a length of the side surface of the connection electrode ANC in the third direction DR3, a length of the side surface of the reflective electrode RL in the third direction DR3, and a length of the side surface of the optical auxiliary film OAL in the third direction DR3.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

A thickness of the first electrode AND located on the top surface of the optical auxiliary film OAL may be less than a thickness of the first electrode AND located on the side surface of the connection electrode ANC, the side surface of the reflective electrode RL, and the side surface of the optical auxiliary film OAL. Accordingly, the first electrode AND located on the top surface of the optical auxiliary film OAL may have a thickness of approximately 50 Å or less, such that light transmittance of the first electrode AND located on the top surface of the optical auxiliary film OAL may be increased. Further, the first electrode AND located on the side surface of the connection electrode ANC, the side surface of the reflective electrode RL, and the side surface of the optical auxiliary film OAL may have a thickness of approximately 100 Å to 200 Å, such that it is possible to prevent a contact resistance from increasing because the first electrode AND is in contact with only the side surface of the connection electrode ANC and the side surface of the reflective electrode RL.

The pixel defining film PDL may be located on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3.

The first pixel defining film PDL1 may be located on the first electrode AND of each of the light emitting elements LE. Specifically, the first pixel defining film PDL1 may cover a part of the first electrode AND located on the top surface of the optical auxiliary film OAL. Further, the first pixel defining film PDL1 may cover the first electrode AND located on the side surface of the connection electrode ANC, the side surface of the reflective electrode RL, and the side surface of the optical auxiliary film OAL. Further, the first pixel defining film PDL1 may cover the first electrode AND located on a part of the ninth insulating film INS9 in the first area AA1. Further, the first pixel defining film PDL1 may be located on the second area AA2 of the ninth insulating film INS9.

The planarization film PNS may be used to planarize a stepped portion caused by the ninth insulating film INS9, the connection electrode ANC, the first step layer STPL1, the second step layer STPL2, the reflective electrode RL, and the optical auxiliary film OAL. The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2. The planarization film PNS may be located on the first pixel defining film PDL1 located in the second area AA2 of the ninth insulating film INS9.

The second pixel defining film PDL2 may be located on the first pixel defining film PDL1 and the planarization film PNS, and the third pixel defining film PDL3 may be located on the second pixel defining film PDL2. The first pixel defining film PDL1 and the third pixel defining film PDL3 may include silicon nitride (SiNx)-based inorganic films, whereas the second pixel defining film PDL2 and the planarization film PNS may include silicon oxide (SiOx)-based inorganic films. The first pixel defining film PDL1 may include a material different from that of the planarization film PNS, and thus may serve as a stopper in a chemical mechanical polishing process for the planarization film PNS.

Each of a thickness of the first pixel defining film PDL1, a thickness of the second pixel defining film PDL2, and a thickness of the third pixel defining film PDL3 may be approximately 500 Å, but the present disclosure is not limited thereto.

When the first pixel defining film PDL1, the second pixel defining film PDL2, and the third pixel defining film PDL3 are formed as one pixel defining film, a height of the one pixel defining film increases, and the second electrode CAT may be cut off due to step coverage. Step coverage refers to a ratio of a thin film coated on an inclined portion to a thin film coated on a flat portion. The lower the step coverage, the more likely it is that the thin film will be cut off at an inclined portion.

In order to reduce or prevent the likelihood of a first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a horizontal length of the first pixel defining film PDL1 defined in the first direction DR1 or the second direction DR2.

Each of the plurality of trenches TRC may penetrate the first pixel defining film PDL1, the planarization film PNS, the second pixel defining film PDL2, and the third pixel defining film PDL3. Further, the ninth insulating film INS9 may be partially recessed at each of the plurality of trenches TRC.

At least one trench TRC may be located between adjacent emission areas EA1, EA2, and EA3. Although FIGS. 7 and 8 illustrate that two trenches TRC are located between neighboring emission areas EA1, EA2, and EA3, the embodiment of the present disclosure is not limited thereto.

The light emitting stack IL may include a plurality of stack layers IL1, IL2, and IL3. FIGS. 7 and 8 illustrate that the light emitting stack IL has a three-tandem structure including a first stack layer IL1, a second stack layer IL2, and a third stack layer IL3, but the embodiment of the present disclosure is not limited thereto. For example, the light emitting stack IL may have a two-tandem structure including two stack layers.

In the three-tandem structure, the light emitting stack IL may have a tandem structure including a plurality of stack layers IL1, IL2, and IL3 that emit different lights. For example, the light emitting stack IL may include the first stack layer IL1 that emits first light, the second stack layer IL2 that emits third light, and the third stack layer IL3 that emits second light. The first stack layer IL1, the second stack layer IL2, and the third stack layer IL3 may be sequentially stacked.

The first stack layer IL1 may have a structure in which a first hole transport layer, a first organic light emitting layer that emits the first light, and a first electron transport layer are sequentially stacked. The second stack layer IL2 may have a structure in which a second hole transport layer, a second organic light emitting layer that emits the second light, and a second electron transport layer are sequentially stacked. The third stack layer IL3 may have a structure in which a third hole transport layer, a third light emitting layer that emits the third light, and a third electron transport layer are sequentially stacked. Here, the first organic light emitting layer, the second organic light emitting layer, and the third organic light emitting layer may provide lights of different colors (or wavelengths). For example, one of the first organic light emitting layer, the second organic light emitting layer, and the third organic light emitting layer may provide light of a first color (e.g., green), another organic light emitting layer may provide light of a second color (e.g., red), and yet another organic light emitting layer may provide light of a third color (e.g., blue).

A first charge generation layer for supplying charges to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND the pixel defining film PDL. A residual film RIL including the same material as the first stack layer IL1 may be located on a bottom surface of each of the trenches TRC. Due to the trench TRC, the first stack layer IL1 may be cut off between neighboring sub-pixels SP1, SP2, and SP3. The second stack layer IL2 may be located on the first stack layer IL1. Due to the trench TRC, the second stack layer IL2 may be cut off between neighboring sub-pixels SP1, SP2, and SP3. A cavity ESS or an empty space may be located between the residual film RIL and the second stack layer IL2 in each trench TRC. The third stack layer IL3 may be located on the second stack layer IL2. The third stack layer IL3 may not be cut off by the trench TRC and may be located to cover the second stack layer IL2 in each of the trenches TRC.

Therefore, in the three-tandem structure, each of the plurality of trenches TRC may be a structure for cutting off the first charge generation layer and the second charge generation layer of the display element layer EML because a current may flow through the first charge generation layer and the second charge generation layer between the sub-pixels SP1, SP2, and SP3 adjacent to each other. In addition, in the two-tandem structure, each of the plurality of trenches TRC may be a structure for cutting off a charge generation layer located between a lower stack layer and an upper stack layer since a current may flow through the charge generation layer.

In order to stably cut off the first charge generation layer and the second charge generation layer of the display element layer EML between neighboring emission areas EA1, EA2, and EA3, a height of each of the plurality of trenches TRC may be greater than a height of the pixel defining film PDL and a height of the planarization film PNS. The height of each of the plurality of trenches TRC refers to a length of each of the plurality of trenches TRC in the third direction DR3. The height of the pixel defining film PDL refers to a length of the pixel defining film PDL in the third direction DR3. The height of the planarization film PNS refers to a length of the planarization film PNS in the third direction DR3.

In order to cut off the first and second charge generation layers of the display element layer EML between the adjacent emission areas EA1, EA2, and EA3, another structure may be used instead of the trench TRC. For example, instead of the trench TRC, a reverse tapered partition wall may be located on the pixel defining film PDL.

The second electrode CAT may be located on the light emitting stack IL. The second electrode CAT may be located on the third stack layer IL3 in each of the plurality of trenches TRC. The second electrode CAT may include a transparent conductive material (TCO), or a semi-transmissive conductive material such as magnesium (Mg), silver (Ag), or an alloy of magnesium (Mg) and silver (Ag). In this case, light emission efficiency in each of the first to third sub-pixels SP1, SP2, and SP3 may be increased due to a micro-cavity effect.

The encapsulation layer TFE may be located on the display element layer EML. The encapsulation layer TFE may include at least one inorganic film TFE1 and/or TFE2 to reduce or prevent oxygen or moisture from permeating into the display element layer EML. For example, the encapsulation layer TFE may include a first encapsulation inorganic film TFE1, and a second encapsulation inorganic film TFE2.

The first encapsulation inorganic film TFE1 may be located on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapordeposition (CVD) process.

The second encapsulation inorganic film TFE2 may be located on the first encapsulation inorganic film TFE1. The second encapsulation inorganic film TFE2 may include titanium oxide (TiOx) or aluminum oxide (AlOx), but the embodiment of the present disclosure is not limited thereto. The second encapsulation inorganic film TFE2 may be formed by an atomic layer deposition (ALD) process. A thickness of the second encapsulation inorganic film TFE2 may be less than a thickness of the first encapsulation inorganic film TFE1.

An organic film APL may be used to increase interfacial adhesion between the encapsulation layer TFE and the optical layer OPL. The organic film APL may be an organic film such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on an adhesive layer ADL.

The first color filter CF1 may overlap the first emission area EA1 of the first sub-pixel SP1. The first color filter CF1 may transmit the first light (e.g., light of a red wavelength band). Thus, the first color filter CF1 may transmit the first light among light emitted from the light emitting stack IL of the first emission area EA1.

The second color filter CF2 may overlap the second emission area EA2 of the second sub-pixel SP2. The second color filter CF2 may transmit the second light (e.g., light of a green wavelength band). Thus, the second color filter CF2 may transmit the second light among light emitted from the light emitting stack IL of the second emission area EA2.

The third color filter CF3 may overlap the third emission area EA3 of the third sub-pixel SP3. The third color filter CF3 may transmit the third light (e.g., light of a blue wavelength band). Thus, the third color filter CF3 may transmit the third light among light emitted from the light emitting stack IL of the third emission area EA3.

The plurality of lenses LNS may be arranged on the first color filter CF1, the second color filter CF2, and the third color filter CF3, respectively. Each of the plurality of lenses LNS may be used to increase a proportion of light directed to a front of the display device 10. Although each of the lenses LNS is illustrated as having a cross-sectional shape that is convex upward, the embodiment of the present disclosure is not limited thereto.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, the cover layer CVL may be attached onto the filling layer FIL. In this case, the filling layer FIL may serve to bond the cover layer CVL. When the cover layer CVL is a glass substrate, the cover layer CVL may serve as an encapsulation substrate. When the cover layer CVL is a polymer resin, the cover layer CVL may be directly applied onto the filling layer FIL.

The polarizing plate POL may be located on one surface of the cover layer CVL. The polarizing plate POL may be used to reduce or prevent visibility degradation caused by reflection of external light. The polarizing plate POL may include a linear polarizing plate and a phase retardation film. For example, the phase retardation film may be a 24 plate (quarter-wave plate), but the embodiment of the present disclosure is not limited thereto. However, when visibility degradation caused by reflection of external light is sufficiently overcome by the first to third color filters CF1, CF2, and CF3, the polarizing plate POL may be omitted.

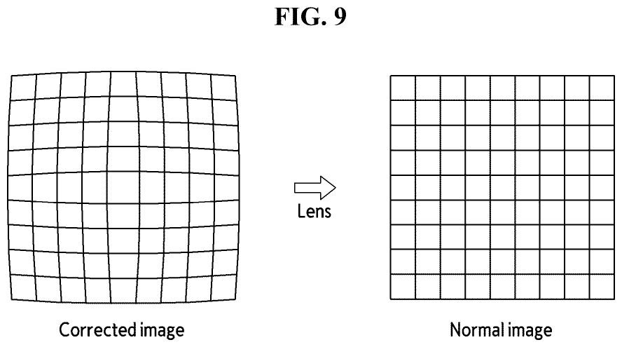

FIG. 9 is a diagram for describing an image correction method of the display device 10 according to one embodiment.

As described above, the display device 10 of one embodiment may include the plurality of lenses LNS, and thus, light from the display element layer EML may be distorted by the lenses LNS. In other words, the image from the display element layer EML may be distorted by the lenses LNS.

To prevent image distortion caused by the lenses LNS, the display device 10 of one embodiment may generate an image (e.g., a corrected image) distorted in a direction opposite to the distortion direction of the distorted image caused by the lens LNS. For example, the timing control circuit 400 of the display device 10 may correct the digital video data DATA from the outside in advance, taking into account the distortion direction of the image caused by the lens LNS as described above. In other words, the timing control circuit 400 may generate corrected digital video data by correcting digital video data DATA from outside. The data driver 700 may convert the corrected digital video data from the timing control circuit 400 into analog data voltages (e.g., corrected data voltages) and output the converted voltages to the data lines DL. Accordingly, the display element layer EML of the display panel 100 may provide light (e.g., corrected light or corrected image) according to the corrected data voltage. The corrected light (or corrected image) may be such that the corrected light is distorted when passing through the lenses LNS and an image (e.g., a normal image) expressed by the light that has passed through the lenses LNS may be displayed without distortion.

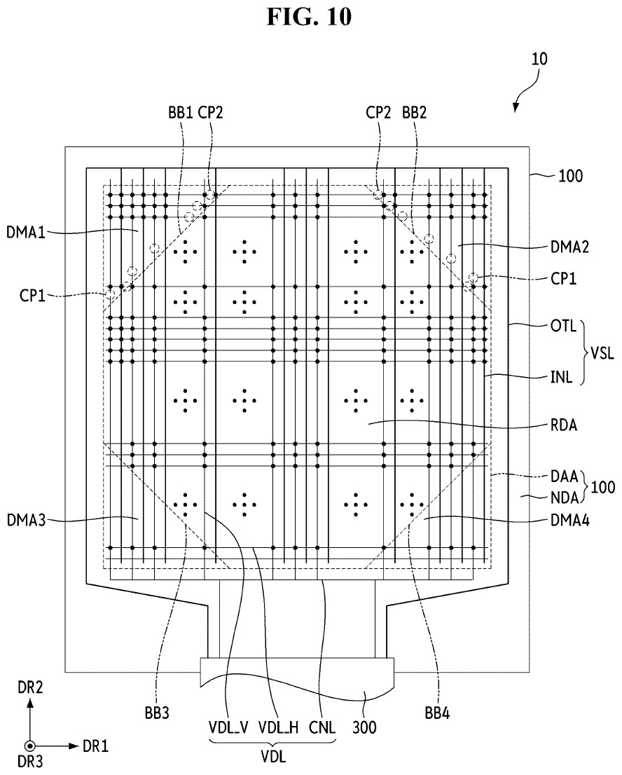

In some embodiments, a partial area of the display area may not be used to generate the above-described corrected image. This will be described in detail with reference to FIG. 10 below.

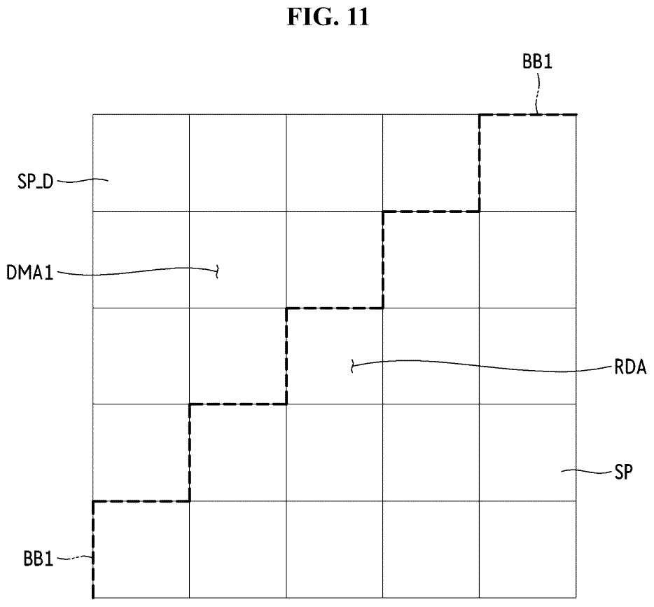

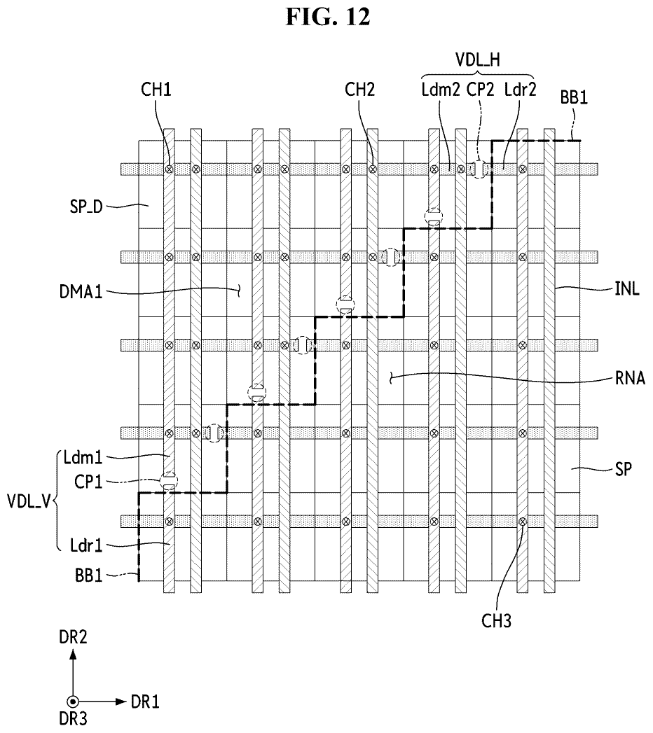

FIG. 10 is a plan view of the display device 10 according to one embodiment, and FIG. 11 is an enlarged view of a portion of a first dummy area DMA1 of FIG. 10. FIG. 12 is a view in which vertical driving voltage lines VDL_V, horizontal driving voltage lines VDL_H, and inner driving voltage lines INL are added to FIG. 11. While FIGS. 11-12 describe configurations in the first dummy area DMA1 of FIG. 10, the descriptions provided with reference to FIGS. 11-12 may be applied for the second dummy area DMA2 of FIG. 10.

The display device 10 according to one embodiment may include the display panel 100 having the display area DAA and the non-display area NDA, as illustrated in FIG. 10. Here, the display area DAA may include a real display area RDA and a plurality of dummy areas DMA1, DMA2, DMA3, and DMA4.

The real display area RDA may be located in a center area of the display area DAA. The real display area RDA may display an image. For example, the above-described corrected image may be provided through the real display area RDA. A plurality of sub-pixels SP may be arranged in the real display area RDA. The plurality of sub-pixels SP in the real display area RDA may display an image (e.g., corrected image). The real display area RDA may have an octagonal shape. However, the shape of the real display area RDA is not limited thereto and may be modified in various ways.

The plurality of dummy areas DMA1, DMA2, DMA3, and DMA4 may be arranged at edge areas of the display area DAA. The plurality of dummy areas DMA1, DMA2, DMA3, and DMA4 may not display an image. A plurality of dummy sub-pixels SP_D may be arranged in the plurality of dummy areas DMA1, DMA2, DMA3, and DMA4. The plurality of dummy areas DMA1, DMA2, DMA3, and DMA4 may include the first dummy area DMA1, a second dummy area DMA2, a third dummy area DMA3, and a fourth dummy area DMA4 separated from each other by the real display area RDA. Each of the dummy areas DMA1, DMA2, DMA3, and DMA4 may have a triangular shape. However, a shape of the dummy areas DMA1, DMA2, DMA3, and DMA4 is not limited thereto and may be variously changed.

The first dummy area DMA1 may be located at an upper left corner of the real display area RDA, the second dummy area DMA2 may be located at an upper right corner of the real display area RDA, the third dummy area DMA3 may be located at a lower left corner of the real display area RDA, and the fourth dummy area DMA4 may be located at a lower right corner of the real display area RDA.

A dummy sub-pixel SP_D included in the first dummy area DMA1 may have the same configuration as the sub-pixel SP. However, a light emitting element of the dummy sub-pixel SP_D may not emit light.

In this way, in order to generate a corrected image, an image may be displayed only in the real display area RDA in the display area DAA, and an image may not be displayed in the dummy areas DMA1, DMA2, DMA3, and DMA4.

The first driving voltage line VSL may be located on the eighth insulating layer INS8. The first driving voltage line VSL may include the same material as the eighth conductive layer ML8.

The first driving voltage line VSL may include an outer driving voltage line OTL and a plurality of inner driving voltage lines INL.

The outer driving voltage line OTL may be located in the non-display area NDA to surround the display area DAA together with the circuit board 300. The outer driving voltage line OTL may be connected to the power supply circuit 500 through the circuit board 300. The first driving voltage VSS from the power supply circuit 500 may be applied to the outer driving voltage line OTL. The second electrode CAT may extend into the non-display area NDA and be connected to the outer driving voltage line OTL. For example, the second electrode CAT may be connected to the outer driving voltage line OTL through via holes in insulating layers in the non-display area NDA.

The inner driving voltage lines INL may be arranged in the display area DAA. The inner driving voltage lines INL may extend into the non-display area NDA and be connected to the outer driving voltage line OTL. The inner driving voltage lines INL and the outer driving voltage line OTL may be formed integrally. The inner driving voltage lines INL may be arranged along the first direction DR1. Each of the inner driving voltage lines INL may extend along the second direction DR2.

The second driving voltage line VDL may include a connection line CNL, a plurality of vertical driving voltage lines VDL_V and a plurality of horizontal driving voltage lines VDL_H.

The connection line CNL may be located in the non-display area NDA. The connection line CNL may be connected to the power supply circuit 500 through the circuit board 300. The second driving voltage VDD from the power supply circuit 500 may be applied to the connection line CNL.

The vertical driving voltage lines VDL_V may be arranged in the display area DAA. The vertical driving voltage lines VDL_V may extend to the non-display area NDA and connected to the connection line CNL. The vertical driving voltage lines VDL_V and the connection line CNL may be formed integrally. The vertical driving voltage lines VDL_V may be arranged along the first direction DR1. Each of the vertical driving voltage lines VDL_V may extend along the second direction DR2. The vertical driving voltage lines VDL_V may be arranged on the eighth insulating layer INS8. Each of the vertical driving voltage lines VDL_V may include the same material as the eighth conductive layer ML8. The vertical driving voltage lines VDL_V and the inner driving voltage lines INL may be alternately arranged. The vertical driving voltage line VDL_V and the inner driving voltage line INL may be parallel to each other.

The horizontal driving voltage lines VDL_H may be arranged in the display area DAA. The horizontal driving voltage lines VDL_H may be arranged along the second direction DR2. Each of the horizontal driving voltage lines VDL_H may extend along the first direction DR1. The horizontal driving voltage lines VDL_H may intersect the vertical driving voltage lines VDL_V and the inner driving voltage lines INL. The horizontal driving voltage lines VDL_H may be arranged on the seventh insulating layer INS7. Each of the horizontal driving voltage lines VDL_H may include the same material as the seventh conductive layer ML7.

At a boundary portion BB1 (hereinafter, referred to as a first boundary portion BB1) between the real display area RDA and the first dummy area DMA1, each of the vertical driving voltage lines VDL_V described above may be cut. For example, at least a portion of the vertical driving voltage line VDL_V located in the first dummy area DMA1 may be cut, and a cut portion CP1 (hereinafter, referred to as a first cut portion CP1) of the vertical driving voltage line VDL_V may be located adjacent to the first boundary portion BB1 in the first dummy area DMA1. In other words, the vertical driving voltage line VDL_V overlapping the first dummy area DMA1 may have the first cut portion CP1 adjacent to the first boundary portion BB1. First cut portions CP1 of the first dummy area DMA1 may be arranged along the first boundary portion BB1.

Similarly, at a boundary portion BB2 (hereinafter, referred to as a second boundary portion BB2) between the real display area RDA and the second dummy area DMA2, each of the vertical driving voltage lines VDL_V described above may be cut. For example, at least a portion of the vertical driving voltage line VDL_V located in the second dummy area DMA2 may be cut, and the first cut portion CP1 of the vertical driving voltage line VDL_V may be located adjacent to the second boundary portion BB2 in the second dummy area DMA2. In other words, the vertical driving voltage line VDL_V overlapping the second dummy area DMA2 may have the first cut portion CP1 adjacent to the second boundary portion BB2. First cut portions CP1 of the second dummy area DMA2 may be arranged along the second boundary portion BB2.

In some embodiments, the vertical driving voltage line VDL_V may not be cut in the real display area RDA, the third dummy area DMA3, and the fourth dummy area DMA4. For example, among the first to fourth dummy areas DMA1 to DMA4, upper dummy areas (e.g., the first dummy area DMA1 and the second dummy area DMA2) may be located farther from the circuit board 300 than lower dummy areas (e.g., the third dummy area DMA3 and the fourth dummy area DMA4), and each of the vertical driving voltage lines VDL_V in the upper dummy areas DMA1 and DMA2 may have the first cut portion CP1, whereas the vertical driving voltage lines VDL_V in the lower dummy areas DMA3 and DMA4 and the real display area RDA may not have the first cut portion CP1. For example, the first cut portion CP1 may not be located in the real display area RDA, the first cut portion CP1 may not be located in the third dummy area DMA3 adjacent to a boundary portion (hereinafter, referred to as a third boundary portion BB3) between the real display area RDA and the third dummy area DMA3, and the first cut portion CP1 may not be located in the fourth dummy area DMA4 adjacent to a boundary portion (hereinafter, referred to as a fourth boundary portion BB4) between the real display area RDA and the fourth dummy area DMA4.

Accordingly, as illustrated in FIG. 12, the vertical driving voltage line VDL_V overlapping the first dummy area DMA1 may include a first driving line Ldr1 and a first dummy line Ldm1 that are separated from each other. For example, the vertical driving voltage line VDL_V may include the first cut portion CP1, the first driving line Ldr1, and the first dummy line Ldm1. The first dummy line Ldm1 may be located in the first dummy area DMA1, and the first driving line Ldr1 may be located in the real display area RDA. In an embodiment, a portion of the first driving line Ldr1 may be located in the first dummy area DMA1 and the third dummy area DMA3. The first driving line Ldr1 may be connected to the connection line CNL, and the first dummy line Ldm1 may not be connected to the connection line CNL.

Similarly, the vertical driving voltage line VDL_V overlapping the second dummy area DMA2 may include a first driving line Ldr1 and a first dummy line Ldm1 that are separated from each other. For example, the vertical driving voltage line VDL_V overlapping the second dummy area DMA2 may include the first cut portion CP1, the first driving line Ldr1, and the first dummy line Ldm1. The first dummy line Ldm1 of the vertical driving voltage line VDL_V overlapping the second dummy area DMA2 may be located in the second dummy area DMA2, and the first driving line Ldr1 of the vertical driving voltage line VDL_V overlapping the second dummy area DMA2 may be located in the real display area RDA. In an embodiment, a portion of the first driving line Ldr1 of the vertical driving voltage line VDL_V overlapping the second dummy area DMA2 may be located in the second dummy area DMA2 and the fourth dummy area DMA4. The first driving line Ldr1 of the vertical driving voltage line VDL_V overlapping the second dummy area DMA2 is may be connected to the connection line CNL, and the first dummy line Ldm1 of the vertical driving voltage line VDL_V overlapping the second dummy area DMA2 may not be connected to the connection line CNL.

At the first boundary portion BB1, each of the horizontal driving voltage lines VDL_H may be cut. For example, at least a portion of the horizontal driving voltage line VDL_H located in the first dummy area DMA1 may be cut, and a cut portion (hereinafter, referred to as a second cut portion CP2) of the horizontal driving voltage line VDL_H may be located adjacent to the first boundary portion BB1 in the first dummy area DMA1. In other words, the horizontal driving voltage line VDL_H overlapping the first dummy area DMA1 may have the second cut portion CP2 adjacent to the first boundary portion BB1. Second cut portions CP2 of the first dummy area DMA1 may be arranged along the first boundary portion BB1.

Similarly, at the second boundary portion BB2, each of the horizontal driving voltage lines VDL_H described above may be cut. For example, at least a portion of the horizontal driving voltage line VDL_H located in the second dummy area DMA2 may be cut, and the second cut portion CP2 of the horizontal driving voltage line VDL_H may be located adjacent to the second boundary portion BB2 in the second dummy area DMA2. In other words, the horizontal driving voltage line VDL_H overlapping the second dummy area DMA2 may have the second cut portion CP2 adjacent to the second boundary portion BB2. Second cut portions CP2 of the second dummy area DMA2 may be arranged along the second boundary portion BB2.

In some embodiments, the horizontal driving voltage line VDL_H may not be cut in the real display area RDA, the third dummy area DMA3, and the fourth dummy area DMA4. For example, in the upper dummy areas DMA1 and DMA2, each of the horizontal driving voltage lines VDL_H may have the second cut portion CP2, whereas in the lower dummy areas DMA3 and DMA4 and the real display area RDA, the horizontal driving voltage lines VDL_H may not have the second cut portion CP2. For example, the second cut portion CP2 may not be located in the real display area RDA, the second cut portion CP2 may not be located in the third dummy area DMA3 adjacent to the third boundary portion BB3, and the second cut portion CP2 may not be located in the fourth dummy area DMA4 adjacent to the fourth boundary portion BB4.

Accordingly, as illustrated in FIG. 12, the horizontal driving voltage line VDL_H overlapping the first dummy area DMA1 and the second dummy area DMA2 may include a second driving line Ldr2 and a second dummy line Ldm2 that are separated from each other. For example, the horizontal driving voltage line VDL_H overlapping the first dummy area DMA1 and the second dummy area DMA2 may include the second cut portion CP2, the second driving line Ldr2, and the second dummy line Ldm2. The second dummy line Ldm2 may be located in the first dummy area DMA1 and the second dummy area DMA2.

In the first dummy area DMA1, the vertical driving voltage line VDL_V and the horizontal driving voltage line VDL_H may be connected to each other. For example, the first dummy line Ldm1 and the second dummy line Ldm2 of the first dummy area DMA1 may be connected to each other through a first contact hole CH1 penetrating the insulating layer at an intersection point between the first and second dummy lines Ldm1 and Ldm2. Additionally, in the first dummy area DMA1, the inner driving voltage line INL and the horizontal driving voltage line VDL_H may be connected to each other. For example, the inner driving voltage line INL and the second dummy line Ldm2 of the first dummy area DMA1 may be connected to each other through a second contact hole CH2 penetrating the insulating layer at an intersection point between the inner driving voltage line INL and the horizontal driving voltage line VDL_H. Accordingly, the horizontal driving voltage line VDL_H of the real display area RDA may be applied with the second driving voltage VDD, whereas the second dummy line Ldm2 (e.g., the cut horizontal driving voltage line VDL_H) of the first dummy area DMA1 may be applied with the first driving voltage VSS instead of the second driving voltage VDD. In other words, the second dummy line Ldm2 of the first dummy area DMA1 may be applied with the first driving voltage VSS from the first driving voltage line VSL.

Similarly, in the second dummy area DMA2, the vertical driving voltage line VDL_V and the horizontal driving voltage line VDL_H may be connected to each other. For example, the first dummy line Ldm1 and the second dummy line Ldm2 of the second dummy area DMA2 may be connected to each other through a first contact hole CH1 penetrating the insulating layer at an intersection point between the first and second dummy lines Ldm1 and Ldm2. Additionally, in the second dummy area DMA2, the inner driving voltage line INL and the horizontal driving voltage line VDL_H may be connected to each other. For example, the inner driving voltage line INL and the second dummy line Ldm2 of the second dummy area DMA2 may be connected to each other through a second contact hole CH2 penetrating the insulating layer at an intersection point between the inner driving voltage line INL and the horizontal driving voltage line VDL_H. Accordingly, the horizontal driving voltage line VDL_H of the real display area RDA may be applied with the second driving voltage VDD, whereas the second dummy line Ldm2 (e.g., the cut horizontal driving voltage line VDL_H) of the second dummy area DMA2 may be applied with the first driving voltage VSS instead of the second driving voltage VDD. In other words, the second dummy line Ldm2 of the second dummy area DMA2 may be applied with the first driving voltage VSS from the first driving voltage line VSL. Accordingly, in the second dummy area DMA2, the second dummy line Ldm2 (e.g., the cut horizontal driving voltage line VDL_H) may be applied with the first driving voltage VSS instead of the second driving voltage VDD. In other words, the second dummy line Ldm2 of the second dummy area DMA2 may be applied with the first driving voltage VSS from the first driving voltage line VSL.

In some embodiments, the horizontal voltage line VDL_H overlapping the third dummy area DMA3 and the fourth dummy area DMA4 may be applied with the second voltage VDD.

In this way, compared to the first driving voltage line VSL in the lower dummy areas DMA3 and DMA4, the first driving voltage line VSL in the upper dummy areas DMA1 and DMA2 may be connected to the horizontal driving voltage line VDL_H (e.g., the second dummy line Ldm2) in addition to the vertical driving voltage line VDL_V (e.g., the first dummy line Ldm1), such that an area of the first driving voltage line VSL may increase in the upper dummy areas DMA1 and DMA2. For example, the first driving voltage line VSL may have a larger area in the upper dummy areas DMA1 and DMA2 than in the lower dummy areas DMA3 and DMA4. Accordingly, voltage drop (e.g., IR drop) of the first driving voltage in the upper dummy areas DMA1 and DMA2 may be reduced. Accordingly, power consumption of the display device 10 may be reduced.

As illustrated in FIG. 12, in the real display area RDA, the horizontal driving voltage line VDL_H may be connected to the vertical driving voltage line VDL_V. For example, in the real display area RDA, the horizontal driving voltage line VDL_H may be connected to the vertical driving voltage line VDL_V through a third contact hole CH3 of the insulating layer. However, in the real display area RDA, the horizontal driving voltage line VDL_H may not be connected to the first driving voltage line VSL (e.g., the inner driving voltage line INL).

Similarly, in the lower dummy areas DMA3 and DMA4, the horizontal driving voltage line VDL_H may be connected to the vertical driving voltage line VDL_V. For example, in the lower dummy areas DMA3 and DMA4, the horizontal driving voltage line VDL_H may be connected to the vertical driving voltage line VDL_V through the contact hole in the insulating layer. However, in the lower dummy areas DMA3 and DMA4, the horizontal driving voltage line VDL_H may not be connected to the first driving voltage line VSL (e.g., the inner driving voltage line INL).

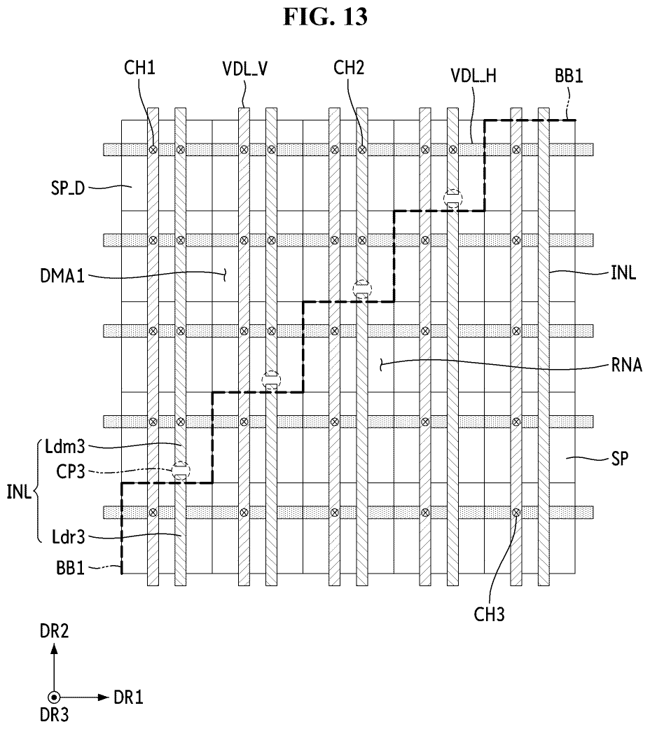

FIG. 13 is a plan view of a display device according to one embodiment.

As illustrated in FIG. 13, in order to reduce the voltage drop of the second driving voltage VDD instead of the first driving voltage VSS, the inner driving voltage line INL instead of the vertical driving voltage line VDL_V may be cut in the upper dummy areas DMA1 and DMA2. For example, the inner driving voltage lines INL overlapping the upper dummy areas DMA1 and DMA2 may have a cut portion CP3 (hereinafter, a third cut portion CP3) in the upper dummy areas DMA1 and DMA2. In other words, the inner driving voltage lines INL overlapping the upper dummy areas DMA1 and DMA2 may include the cut portion CP3, a third driving line Ldr3, and a third dummy line Ldm3. In an embodiment, the third driving line Ldr3 may be connected to the outer driving voltage line OTL, and the third dummy line Ldm3 may be separated from the outer driving voltage line OTL.

The third cut portion CP3 of the first dummy area DMA1 may be located close to the first boundary portion BB1. The third cut portions CP3 of the first dummy area DMA1 may be arranged along the first boundary portion BB1.

The third cut portion CP3 of the second dummy area DMA2 may be located close to the second boundary portion BB2. The third cut portions CP3 of the second dummy area DMA2 may be arranged along the second boundary portion BB2.

In each of the dummy areas DMA1 to DMA4 and the real display area RDA, the vertical driving voltage line VDL_V and the horizontal driving voltage line VDL_H may be connected to each other. For example, in each of the dummy areas DMA1 to DMA4 and the real display area RDA, the vertical driving voltage line VDL_V and the horizontal driving voltage line VDL_H may be connected to each other through the first contact hole CH1 penetrating the insulating layer at an intersection point between the vertical driving voltage line VDL_V and the horizontal driving voltage line VDL_H.

Additionally, in the first dummy area DMA1, the inner driving voltage line INL and the horizontal driving voltage line VDL_H may be connected to each other. For example, the third dummy line Ldm3 of the first dummy area DMA1 and the horizontal driving voltage line VDL_H may be connected to each other through the second contact hole CH2 penetrating the insulating layer at an intersection point between the third dummy line Ldm3 and the horizontal driving voltage line VDL_H.

Further, in the real display area RDA, the horizontal driving voltage line VDL_H may be connected to the vertical driving voltage line VDL_V. For example, in the real display area RDA, the horizontal driving voltage line VDL_H may be connected to the vertical driving voltage line VDL_V through a third contact hole CH3 of the insulating layer. However, in the real display area RDA, the horizontal driving voltage line VDL_H may not be connected to the first driving voltage line VSL (e.g., the inner driving voltage line INL).

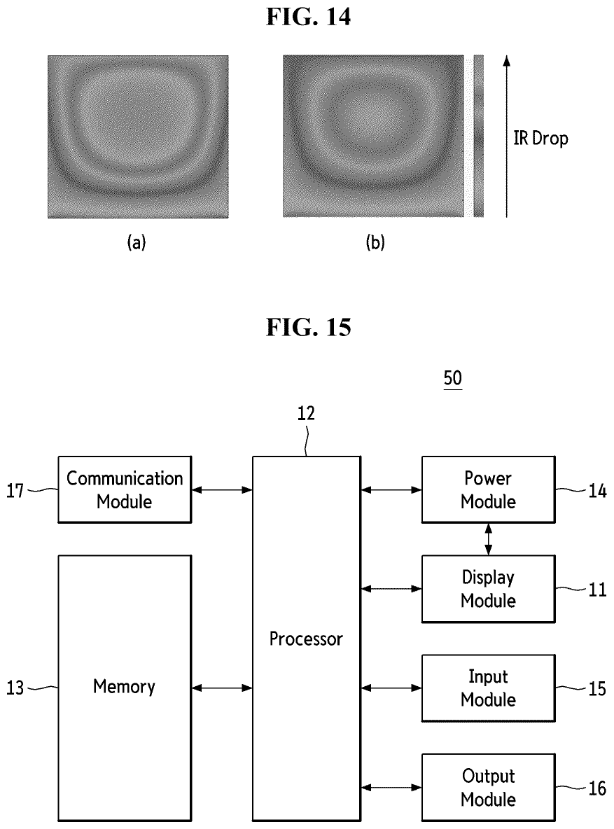

FIG. 14 is a drawing for describing an effect of reducing voltage drop of the display device 10 according to one embodiment.

In FIG. 14, (a) is a drawing illustrating distribution of voltage drop in a display device of a comparative example, and (b) is a drawing illustrating distribution of voltage drop in the display device 10 according to one embodiment.

As illustrated in FIG. 14, it may be seen that the voltage drop of the display device 10 according to one embodiment is smaller than the voltage drop of the display device of the comparative example. In particular, it may be seen that a magnitude of the voltage drop in an upper portion of the display device 10 in which the upper dummy areas are arranged in the display device 10 of one embodiment is significantly reduced compared to the display device of the comparative example. In an embodiment, the voltage drop of the first driving voltage VSS may be further reduced by about 15 mV to 80 mV.

The display device 10 according to the embodiment may be applied to various electronic devices. An electronic device according to one embodiment may include the above-described display device 10, and may further include, in addition to the display device 10, a module or device having other additional functions.

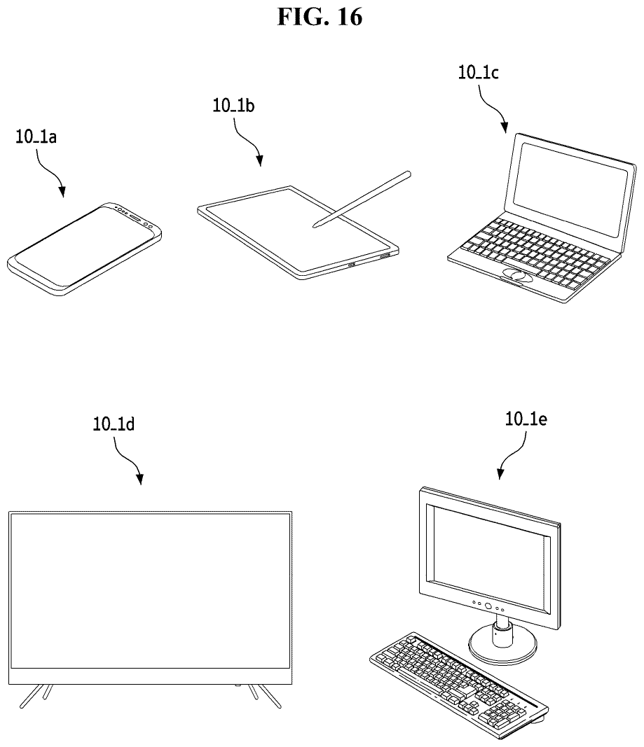

FIG. 15 is a block diagram of an electronic device according to one embodiment. Referring to FIG. 15, an electronic device 50 according to one embodiment may include a display module 11, a processor 12, a memory 13, and a power module 14. The electronic device 50 may further include an input module 15, a non-visual output module 16, and/or a communication module 17.

The electronic device 50 may output various information in a form of images through the display module 11. When the processor 12 executes an application stored in memory 13, image information provided by the application may be provided to a user through the display module 11. The power module 14 may include a power supply module, such as a power adapter or a battery device, and a power conversion module that converts the power supplied by the power supply module to generate the power required for the operation of the electronic device 50. The input module 15 may provide input information to the processor 12 and/or the display module 11. The non-visual output module 16 may serve to receive information other than images, such as sound, haptics, luminescence, etc., sent from the processor 12, and provide the information to the user. The communication module 17 may perform transmission and/or reception of information between the electronic device 50 and an external device, and may include a receiver and/or a transmitter.

At least one of each of the components of the above-described electronic device 50 may be included in the display device according to the embodiments described above. In addition, some of the individual modules that are functionally included in a single module may be included in the display device, whereas some others thereof may be provided separately from the display device. For example, the display device may include the display module 11, whereas the processor 12, the memory 13 and the power module 14 may be provided in a form of other devices in the electronic device 50, other than the display device.

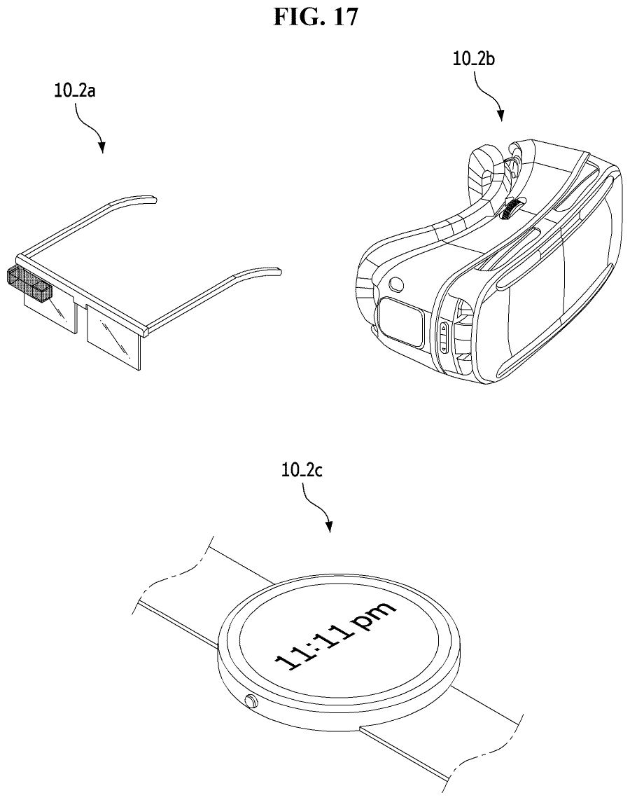

FIGS. 16, 17 and 18 are schematic diagrams illustrating electronic devices according to various embodiments. FIGS. 16 to 18 illustrate examples of various electronic devices to which the display device 10 according to the above-described embodiments are applied.

FIG. 16 shows a smartphone 10_1a, a tablet PC 10_1b, a laptop 10_1c, a TV 10_1d, and a desk monitor 10_1e as examples of electronic devices.

The smartphone 10_1a may include a communication module and an input module such as a touch sensor, etc., in addition to the display module 11. The smartphone 10_1a may process the information received through the communication module or input module and display the processed information through the display module of the display device.

Each of the tablet PC 10_1b, the laptop 10_1c, the TV 10_1d, and the desk monitor 10_1e may include a display and an input module, similarly to the smartphone 10_1a, and may further include a communication module in some cases.

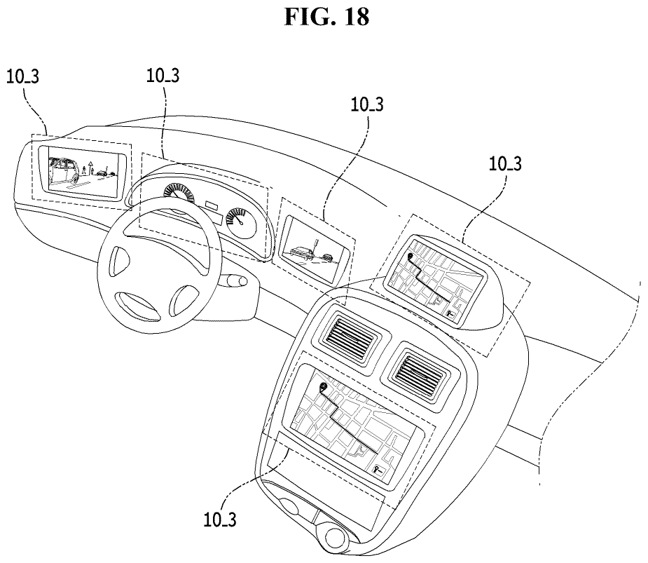

FIG. 17 illustrates a case in which an electronic device including a display module is applied to a wearable electronic device. The wearable electronic device may be smart glasses 10_2a, a head mounted display 10_2b, a smart watch 10_2c, and the like.

The smart glasses 10_2a and the head mounted display 10_2b may include a display module that outputs a display image and a reflector that reflects the outputted display image to be provided to the user's eyes, thereby providing the user with a virtual reality or augmented reality screen.

The smart watch 10_2c may include a biometric sensor as an input device, and may provide biometric information recognized through the biometric sensor to the user through a display module.

FIG. 18 illustrates a case in which an electronic device including a display module is applied to a vehicle. For example, an electronic device 10_3 may be applied to a dashboard or center fascia of a vehicle, or to a center information display (CID) placed in the dashboard of the vehicle or a room mirror display that replaces a side mirror.

According to one embodiment, power consumption of the display device and the electronic device may be reduced.

For example, according to one embodiment, a second driving voltage line may be cut in a dummy area, and a portion of the cut second driving voltage line may be connected to a first driving voltage line, such that the area of the first driving voltage line may be increased. Accordingly, the voltage drop (e.g., IR drop) of the first driving voltage may be reduced. Accordingly, the power consumption of the display device may be reduced.

The effects of the present disclosure are not limited to the above-described effects and other effects which are not described herein will become apparent to those skilled in the art from the following description.

At least one of the components, elements, modules or units (collectively “components” in this paragraph) represented by a block in the drawings, may be embodied as various numbers of hardware, software and/or firmware structures that execute respective functions described above, according to one or more example embodiments. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A display device comprising:
a display panel having a display area and a non-display area;
a circuit board connected to the non-display area of the display panel;
a sub-pixel in a real display area of the display area;
a dummy sub-pixel in a dummy area of the non-display area;
a first driving voltage line connected to a power supply circuit of the circuit board; and
a second driving voltage line connected to the power supply circuit,
wherein the first driving voltage line comprises an outer driving voltage line in the non-display area and an inner driving voltage line in the display area and the dummy area,
wherein the second driving voltage line comprises a connection line in the non-display area, a vertical driving voltage line in the display area and in the dummy area, and a horizontal driving voltage line in the display area and in the dummy area, and
wherein a first portion of the vertical driving voltage line is cut in the dummy area and a second portion of the vertical driving voltage line is connected to the first driving voltage line in the dummy area.

2. The display device of claim 1, wherein the vertical driving voltage line comprises a first driving line and a first dummy line that are separated by a first cut portion of the vertical driving voltage line, and
wherein at least a portion of the first driving line is in the real display area.

3. The display device of claim 2, wherein a first portion of the horizontal driving voltage line is cut in the dummy area, and a second portion of the horizontal driving voltage line is connected to the first dummy line and the first driving voltage line in the dummy area.

4. The display device of claim 3, wherein the horizontal driving voltage line comprises a second driving line and a second dummy line that are separated by a second cut portion of the horizontal driving voltage line, and
wherein at least a portion of the second driving line is in the real display area.

5. The display device of claim 4, wherein the second dummy line is connected to the first dummy line and the inner driving voltage line in the dummy area.

6. The display device of claim 5, wherein the second dummy line and the first dummy line are connected through a contact hole penetrating an insulating layer of the display panel.

7. The display device of claim 5, wherein the second dummy line and the inner driving voltage line are connected through a contact hole penetrating an insulating layer of the display panel.

8. The display device of claim 2, wherein the first cut portion is close to a boundary portion between the dummy area and the real display area.

9. The display device of claim 8, wherein the vertical driving voltage line comprises a plurality of vertical driving voltage lines,
wherein the plurality of vertical driving voltage lines comprise a plurality of first cut portions along the boundary portion.

10. The display device of claim 4, wherein the second cut portion is close to a boundary portion between the dummy area and the real display area.

11. The display device of claim 10, wherein the horizontal driving voltage line comprises a plurality of horizontal driving voltage lines,
wherein the plurality of horizontal driving voltage lines comprise a plurality of second cut portions along the boundary portion.

12. The display device of claim 1, wherein the dummy area comprises a plurality of dummy areas that are separated.

13. The display device of claim 12, wherein the real display area is in a center area of the display area, and
wherein the plurality of dummy areas are at edge areas of the display area.

14. The display device of claim 13, wherein the plurality of dummy areas comprise an upper dummy area and a lower dummy area,
wherein the upper dummy area is farther from the circuit board than the lower dummy area, and
wherein the vertical driving voltage line is cut in the upper dummy area.

15. The display device of claim 14, wherein the horizontal driving voltage line is cut in the upper dummy area.

16. The display device of claim 1, wherein the first driving voltage line is configured to transmit a first driving voltage, and
wherein the second driving voltage line is configured to transmit a second driving voltage greater than the first driving voltage.

17. The display device of claim 1, wherein the vertical driving voltage line comprises a plurality of vertical driving voltage lines and the inner driving voltage line comprises a plurality of inner driving voltage lines, and
wherein the plurality of vertical driving voltage lines and the plurality of inner driving voltage lines alternate.

18. The display device of claim 1, wherein the vertical driving voltage line is parallel with the inner driving voltage line.

19. An electronic device comprising a display device, wherein the display device comprises:
a display panel having a display area and a non-display area;
a circuit board connected to the non-display area;
a sub-pixel in a real display area of the display area;
a dummy sub-pixel in a dummy area of the non-display area;
a first driving voltage line connected to a power supply circuit of the circuit board; and
a second driving voltage line connected to the power supply circuit,
wherein the first driving voltage line comprises an outer driving voltage line in the non-display area and an inner driving voltage line in the display area and the dummy area,
wherein the second driving voltage line comprises a connection line in the non-display area, a vertical driving voltage line in the display area and the dummy area, and a horizontal driving voltage line in the display area and the dummy area, and
wherein a first portion of the vertical driving voltage line is cut in the dummy area and a second portion of the vertical driving voltage line is connected to the first driving voltage line in the dummy area.

20. The electronic device of claim 19, wherein the electronic device comprises at least one of a smartphone, a tablet, a laptop, a television (TV), a desk monitor, smart glasses, a smart watch, a head mounted display or a vehicle.
